(19) United States
(12) Patent Application Publication
(10) Pub. No.: US 2024/0379345 A1
(43) Pub. Date: Nov. 14, 2024

(54) APPARATUS FOR CLEANING A SEMICONDUCTOR FABRICATION CHAMBER

(71) Applicant: Samsung Electronics Co., Ltd., Suwon-si (KR)

(72) Inventors: Jeongmin Hwang, Suwon-si (KR); Jongseong Ko, Suwon-si (KR); Daeyong Kim, Suwon-si (KR); Donghyun Kim, Suwon-si (KR); Jisu Kim, Suwon-si (KR); Pyungkang Kim, Suwon-si (KR); Kihong Park, Suwon-si (KR); Jungjoon Park, Suwon-si (KR); Jungjun Park, Suwon-si (KR); Jooyoung Park, Suwon-si (KR); Junhyeok Park, Suwon-si (KR); Hoseok Song, Suwon-si (KR); Chiho Ahn, Suwon-si (KR); Kongwoo Lee, Suwon-si (KR); Hyunyoung Lee, Suwon-si (KR); Chuyoung Choung, Suwon-si (KR)

(21) Appl. No.: 18/394,524

(22) Filed: Dec. 22, 2023

(30) Foreign Application Priority Data
May 10, 2023 (KR) 10-2023-0060234
Jul. 6, 2023 (KR) 10-2023-0087482

(51) Int. Cl. H01L 21/02; G06T 7/00

(52) U.S. Cl. CPC H01L 21/02098; G06T 7/0004; H01L 21/02101; G06T 2207/30148

(57) ABSTRACT

An apparatus for cleaning a semiconductor fabrication chamber may include a cleaning module, an inspection module and a drive module. The cleaning module may clean an inner area of the semiconductor fabrication chamber in a non-contact manner. The inspection module may be configured to inspect a cleaning of the semiconductor fabrication chamber by the cleaning module. The drive module may be configured to move the cleaning module and the inspection module in the semiconductor fabrication chamber. Thus, the non-contact type cleaning module may effectively remove the contaminant on an inner wall of the semiconductor fabrication chamber having a complicated shape and/or a part on the inner wall of the semiconductor fabrication chamber having a complicated shape.

### CROSS-REFERENCE TO RELATED APPLICATION

This application claims priority under 35 USC § 119 to Korean Patent Application Nos. 10-2023-0060234, filed on May 10, 2023, and 10-2023-0087482, filed on Jul. 6, 2023, in the Korean Intellectual Property Office (KIPO), the contents of which are herein incorporated by reference in their entirety.

### BACKGROUND

### 1. Field

Example embodiments relate to an apparatus for cleaning a semiconductor fabrication chamber. More particularly, example embodiments relate to an apparatus for cleaning a chamber configured to fabricate a semiconductor device.

### 2. Description of the Related Art

Generally, a semiconductor fabrication chamber may process a substrate using plasma generated from a reaction gas. A contaminant generated in processing the substrate may contaminate the semiconductor fabrication chamber.

According to related arts, a cleaning apparatus may include a roller. The roller may rotationally make contact with an inner wall of the semiconductor fabrication chamber to remove the contaminant. However, the roller may not remove the contaminant on the inner wall having a complicated structure or a part on the inner wall having a complicated shape. Thus, the contaminant may be removed by a manual cleaning process.

Further, because the roller may directly make contact with the inner wall of the semiconductor fabrication chamber, the roller may be worn so that the roller may be periodically exchanged for a new one. Particularly, the roller may make contact with the inner wall of the semiconductor fabrication chamber under a high pressure so that the inner wall and/or the part of the semiconductor fabrication chamber may be damaged.

### SUMMARY

Example embodiments provide an apparatus for effectively cleaning a semiconductor fabrication chamber.

According to example embodiments, there may be provided an apparatus for cleaning a semiconductor fabrication chamber. The apparatus may include a cleaning module, an inspection module and a drive module. The cleaning module may clean an inner area of the semiconductor fabrication chamber in a non-contact manner. The inspection module may inspect a cleaning of the semiconductor fabrication chamber by the cleaning module. The drive module may be configured to move the cleaning module and the inspection module in the semiconductor fabrication chamber.

According to example embodiments, there may be provided an apparatus for cleaning a semiconductor fabrication chamber. The apparatus may include a cleaning module, an inspection module, a drive module and a mount module. The cleaning module may clean an inner area of the semiconductor fabrication chamber in a non-contact manner. The inspection module may inspect a cleaning of the semiconductor fabrication chamber by the cleaning module. The drive module may be configured to move the cleaning module and the inspection module in the semiconductor fabrication chamber. The mount module may removably mount the drive module to the semiconductor fabrication chamber. The cleaning module may include a non-contact type cleaner, a cleaner sensor and a cleaner controller. The non-contact type cleaner may clean the inner area of the semiconductor fabrication chamber in the non-contact manner. The cleaner sensor may detect position information of the non-contact type cleaner with respect to the semiconductor fabrication chamber. The cleaner controller may control a position of the non-contact type cleaner based on the position information detected by the cleaner sensor. The inspection module may include an imager, an inspection sensor and an inspection controller. The imager may photograph the inner area of the semiconductor fabrication chamber before and after cleaning the semiconductor fabrication chamber by the cleaning module. The inspection sensor may detect position information of the imager with respect to the semiconductor fabrication chamber. The inspection controller may control a position of the based on the position information detected by the inspection sensor.

According to example embodiments, the cleaning module may effectively remove a contaminant in the semiconductor fabrication chamber in the non-contact manner. Particularly, the non-contact type cleaning module may effectively remove the contaminant on an inner wall of the semiconductor fabrication chamber having a complicated shape and/or a part on the inner wall of the semiconductor fabrication chamber having a complicated shape. Thus, an additional manual cleaning process may not be required.

Further, the non-contact type cleaning module may not directly make contact with the inner wall and/or the part of the semiconductor fabrication chamber so that it may not be required to periodically exchange a part of the cleaning apparatus for a new one. Furthermore, the inner wall and/or the part of the semiconductor fabrication chamber may not be damaged.

### BRIEF DESCRIPTION OF THE DRAWINGS

Example embodiments will be more clearly understood from the following detailed description taken in conjunction with the accompanying drawings. FIGS. 1 to 5 represent non-limiting, example embodiments as described herein.

FIG. 1 is a cross-sectional view illustrating an apparatus for cleaning a semiconductor fabrication chamber in accordance with example embodiments;

FIG. 2 is a plan view illustrating the apparatus in FIG. 1;

FIG. 3 is a block diagram illustrating a non-contact type cleaning module of the apparatus in FIG. 1;

FIG. 4 is a block diagram illustrating an inspection module of the apparatus in FIG. 1; and

FIG. 5 is a block diagram illustrating a drive module of the apparatus in FIG. 1.

### DETAILED DESCRIPTION OF THE EMBODIMENTS

Hereinafter, example embodiments will be explained in detail with reference to the accompanying drawings.

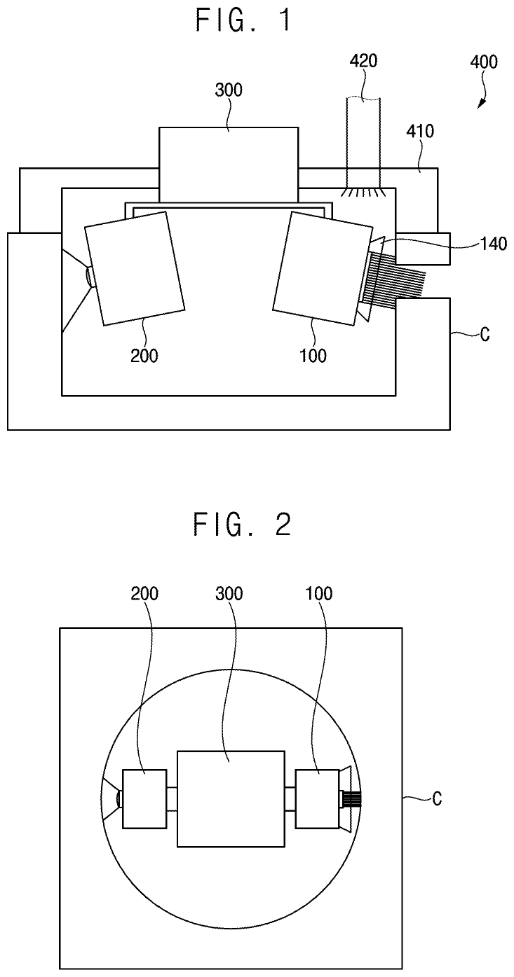

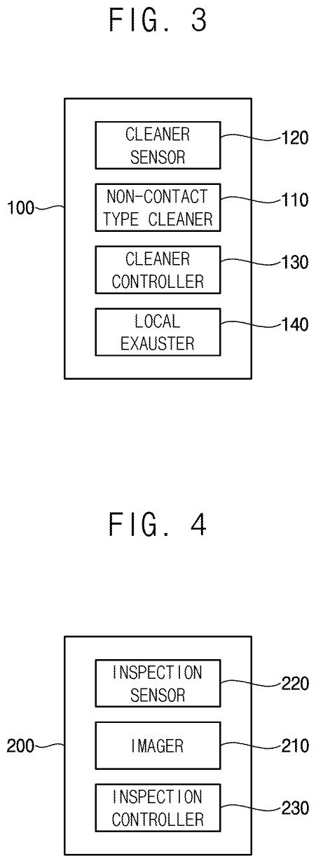

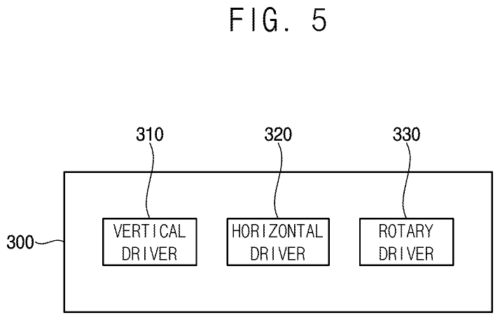

FIG. 1 is a cross-sectional view illustrating an apparatus for cleaning a semiconductor fabrication chamber in accordance with example embodiments, FIG. 2 is a plan view illustrating the apparatus in FIG. 1, FIG. 3 is a block diagram illustrating a non-contact type cleaning module of the apparatus in FIG. 1, FIG. 4 is a block diagram illustrating an inspection module of the apparatus in FIG. 1 and FIG. 5 is a block diagram illustrating a drive module of the apparatus in FIG. 1.

Referring to FIGS. 1 to 5, an apparatus for cleaning a semiconductor fabrication chamber in accordance with example embodiments may clean an inner area of the semiconductor fabrication chamber C in a non-contact manner to remove a contaminant in the inner area of the semiconductor fabrication chamber C. Particularly, the cleaning apparatus may remove the contaminant on an inner wall and/or a part of the semiconductor fabrication chamber C in the non-contact manner.

The semiconductor fabrication chamber C may be used for forming a layer on a semiconductor substrate or for etching a layer on the semiconductor substrate using plasma, but embodiments of the inventive concept are not limited thereto. The semiconductor fabrication chamber C may have a cylindrical shape, but embodiments of the inventive concept are not limited thereto. For example, the semiconductor fabrication chamber C may have a rectangular parallelepiped shape. Further, the semiconductor fabrication chamber C may have an opened upper surface. A lid may be installed at the opened upper surface to open/close the upper surface of the semiconductor fabrication chamber C.

The cleaning apparatus may include a cleaning module 100, an inspection module 200, a drive module 300 and a mount module 400. The cleaning module 100 may clean the inner area of the semiconductor fabrication chamber C in the non-contact manner. The inspection module 200 may inspect a cleaning of the semiconductor fabrication chamber C by the cleaning module 100. The drive module 300 may transfer or move the cleaning module 100 and the inspection module 200 in the semiconductor fabrication chamber C. The mount module 400 may removably mount the drive module to the semiconductor fabrication chamber C. In example embodiments, the cleaning module 100 and the inspection module 200 may be positioned or configured symmetrically with respect to the drive module 300, but embodiments of the inventive concept are not limited thereto.

The cleaning module 100 may be connected to the drive module 300. The cleaning module 100 may selectively enter into the semiconductor fabrication chamber C. The cleaning module 100 may include a non-contact type cleaner 110, a cleaner sensor 120, a cleaner controller 130 and a local exhauster 140.

The non-contact type cleaner 110 may clean the inner area of the semiconductor fabrication chamber C in the non-contact manner. That is, the non-contact type cleaner 110 may clean the inner wall and/or the part of the semiconductor fabrication chamber C in the non-contact manner to remove the contaminant on the inner wall and/or the part of the semiconductor fabrication chamber C. Thus, the non-contact type cleaner 110 may be spaced apart from the inner wall of the semiconductor fabrication chamber C to form a gap between the non-contact type cleaner 110 and the inner wall of the semiconductor fabrication chamber C. When an optimal gap may be formed between the non-contact type cleaner 110 and the inner wall of the semiconductor fabrication chamber C, the non-contact type cleaner 110 may have improved cleaning efficiency. Further, when a uniform gap may be formed between the non-contact type cleaner 110 and the inner wall of the semiconductor fabrication chamber C, all regions on the inner wall of the semiconductor fabrication chamber C may be cleaned by a same cleaning efficiency.

In example embodiments, the non-contact type cleaner 110 may use a laser, a dry ice, etc., but embodiments of the inventive concept are not limited thereto. The non-contact type cleaner 110 using the laser may irradiate the laser to the inner wall and/or the part of the semiconductor fabrication chamber C to drop or remove the contaminant from the inner wall and/or the part of the semiconductor fabrication chamber C. The non-contact type cleaner 110 using the dry ice may inject the dry ice to the inner wall and/or the part of the semiconductor fabrication chamber C to drop the contaminant from the inner wall and/or the part of the semiconductor fabrication chamber C.

The cleaner sensor 120 may detect position information of the non-contact type cleaner 110 with respect to the semiconductor fabrication chamber C. Particularly, the cleaner sensor 120 may be positioned adjacent to the non-contact type cleaner 110 to detect the position information of the non-contact type cleaner 110. The position information may include a distance and/or an angle between the non-contact type cleaner 110 and a surface of the semiconductor fabrication chamber C, but embodiments of the inventive concept are not limited thereto.

The cleaner controller 130 may control a position of the non-contact type cleaner 110 based on the position information detected by the cleaner sensor 120. That is, the inner wall of the semiconductor fabrication chamber C may have various irregular shapes such as a reaction gas inlet hole, a wafer inlet slot, etc. In order to provide the non-contact type cleaner 110 with an optimal posture with respect to the irregular shapes, the cleaner controller 130 may control the position of the non-contact type cleaner 110 based on the position information.

Particularly, the cleaner controller 130 may control a distance between the non-contact type cleaner 110 and the semiconductor fabrication chamber C, a rotation of the non-contact type cleaner 110, etc. The rotation of the non-contact type cleaner 110 may include a roll rotated with respect to a first horizontal direction, a pitch rotated in a second horizontal direction substantially perpendicular to the first horizontal direction, and a yaw rotated with respect to a vertical direction. Thus, the cleaner controller 130 may control the roll, the pitch and the yaw of the non-contact type cleaner 110. Data of the cleaner sensor 120 inputted into the cleaner controller 130 and data of the non-contact type cleaner 110 controlled by the cleaner controller 130 may be data based to be used following cleaning processes.

The local exhauster 140 may be positioned adjacent to the non-contact type cleaner 110. The local exhauster 140 may capture the contaminant dropped from the inner wall and/or the part of semiconductor fabrication chamber C by the non-contact type cleaner 110 to exhaust the contaminant from the semiconductor fabrication chamber C. Thus, the local exhauster 140 may include a vacuum pump, or may be connected to the vacuum pump.

The inspection module 200 may be connected to the drive module 300. The inspection module 200 may selectively enter into the semiconductor fabrication chamber C. As mentioned above, the inspection module 200 may be symmetrical with the cleaning module 100 with respect to the drive module 300, but embodiments of the inventive concept are not limited thereto. The inspection module 200 may include an imager 210, an inspection sensor 220 and an inspection controller 230.

The imager 210 may photograph the inner area of the semiconductor fabrication chamber C before and after cleaning semiconductor fabrication chamber C by the cleaning module 100. That is, the imager 210 may photograph the inner wall of the semiconductor fabrication chamber C before the cleaning process to obtain an image before the cleaning process. Further, the imager 210 may photograph the inner wall of the semiconductor fabrication chamber C after the cleaning process to obtain an image after the cleaning process. A contamination index of the semiconductor fabrication chamber C, a region of the semiconductor fabrication chamber to be cleaned, etc., may be checked based on the image before the cleaning process. Further, the images before and after the cleaning process may be compared with each other to check removal state of the contaminant, i.e., the cleaning efficiency of the cleaning apparatus.

The inspection sensor 220 may detect position information of the imager 210 with respect to the semiconductor fabrication chamber C. Particularly, the inspection sensor 220 may be positioned adjacent to the imager 210 to detect the position information of the imager 210.

The inspection controller 230 may control a position of the imager 210 based on the position information of the imager 210 detected by the inspection sensor 220. Particularly, the inspection controller 230 may control a distance between the imager 210 and the semiconductor fabrication chamber C, a rotation of the imager 210, etc. The rotation of the imager 210 may include the roll rotated with respect to the first horizontal direction, the pitch rotated the second horizontal direction, and the yaw rotated with respect to the vertical direction. Thus, the inspection controller 230 may control the roll, the pitch and the yaw of the imager 210. Data of the inspection sensor 220 inputted into the inspection controller 230 and data of the imager 210 controlled by the inspection controller 230 may be data based to be used following cleaning processes.

The drive module 300 may transfer or move the cleaning module 100 and the inspection module 200 to desired positions in the semiconductor fabrication chamber C. The drive module 300 may include a vertical driver 310, a horizontal driver 320 and a rotary driver 330.

The vertical driver 310 may move the cleaning module 100 and the inspection module 200 in the semiconductor fabrication chamber C along the vertical direction. Thus, the vertical driver 310 may include a vertical actuator configured to generate a vertical drive force. The vertical actuator may include a motor, a cylinder, etc., but embodiments of the inventive concept are not limited thereto.

The horizontal driver 320 may move the cleaning module 100 and the inspection module 200 in the semiconductor fabrication chamber C along the horizontal direction. Thus, the horizontal driver 320 may include a horizontal actuator configured to generate a horizontal drive force. The horizontal actuator may include a motor, a cylinder, etc., but embodiments of the inventive concept are not limited thereto.

The rotary driver 330 may rotate the cleaning module 100 and the inspection module 200 in the semiconductor fabrication chamber C with respect to the vertical direction. Thus, the rotary driver 330 may include a rotary actuator configured to generate a rotary drive force. The rotary actuator may include a motor, a cylinder, etc., but embodiments of the inventive concept are not limited thereto.

The mount module 400 may removably mount the drive module 300 to the semiconductor fabrication chamber C. As mentioned above, the semiconductor fabrication chamber C may have the opened upper surface. Thus, the mount module 400 may removably mount the drive module 300 to the upper surface of the semiconductor fabrication chamber C. By mounting the drive module 300 to the upper surface of the semiconductor fabrication chamber C by the mount module 400, the cleaning module 100 and the inspection module 200 connected to the drive module 300 may enter into the semiconductor fabrication chamber C.

The mount module 400 may include a mount block 410 that is configured to be connected to the drive module 300. The mount block 410 may be removably installed at the upper surface of the semiconductor fabrication chamber C. Additionally, the mount block 410 may further include a main exhauster 420 provided to the mount block 410. The contaminant, which may not be exhausted by the local exhauster 140, may be exhausted through the main exhauster 420. Thus, the main exhauster 420 may include a vacuum pump or may be connected to the vacuum pump. Alternatively, the drive module 300 may be separated from the mount module 400. In this case, the drive module 300 and the mount module 400 may be connected to each other at the upper surface of the semiconductor fabrication chamber C.

According to example embodiments, the cleaning module may effectively remove a contaminant in the semiconductor fabrication chamber in the non-contact manner. Particularly, the non-contact type cleaning module may effectively remove the contaminant on an inner wall of the semiconductor fabrication chamber having a complicated shape and/or a part on the inner wall of the semiconductor fabrication chamber having a complicated shape. Thus, an additional manual cleaning process may not be required.

Further, the non-contact type cleaning module may not directly make contact with the inner wall and/or the part of the semiconductor fabrication chamber so that it may not be required to periodically exchange a part of the cleaning apparatus for a new one. Furthermore, damage to the inner wall and/or the part of the semiconductor fabrication chamber may be reduced or eliminated.

The foregoing is illustrative of example embodiments and is not to be construed as limiting thereof. Although a few example embodiments have been described, those skilled in the art will readily appreciate that many modifications are possible in the example embodiments without departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An apparatus for cleaning a semiconductor fabrication chamber, the apparatus comprising:
a cleaning module configured to clean an inner area of the semiconductor fabrication chamber in a non-contact manner;
an inspection module configured to inspect a cleaning of the semiconductor fabrication chamber by the cleaning module; and
a drive module configured to move the cleaning module and the inspection module in the semiconductor fabrication chamber.

2. The apparatus of claim 1, wherein the cleaning module comprises:
a non-contact type cleaner configured to clean the inner area of the semiconductor fabrication chamber in the non-contact manner;
a cleaner sensor configured to detect position information of the non-contact type cleaner with respect to the semiconductor fabrication chamber; and
a cleaner controller configured to control a position of the non-contact type cleaner based on the position information detected by the cleaner sensor.

3. The apparatus of claim 2, wherein the non-contact type cleaner is configured to clean the inner area of the semiconductor fabrication chamber in the non-contact manner by using a laser or dry ice.

4. The apparatus of claim 2, wherein the position information comprises a distance and/or an angle between the non-contact type cleaner and a surface of the semiconductor fabrication chamber.

5. The apparatus of claim 2, wherein the cleaner controller is configured to control a distance between the non-contact type cleaner and a surface of the semiconductor fabrication chamber, and the cleaner controller further controls a rotation of the non-contact type cleaner.

6. The apparatus of claim 5, wherein the rotation of the non-contact type cleaner comprises a roll rotated with respect to a first horizontal direction, a pitch rotated with respect to a second horizontal direction substantially perpendicular to the first horizontal direction, and a yaw rotated with respect to a vertical direction.

7. The apparatus of claim 2, wherein the cleaning module further comprises a local exhauster configured to exhaust a contaminant, which is removed by the non-contact type cleaner, from the semiconductor fabrication chamber.

8. The apparatus of claim 1, wherein the inspection module comprises:
an imager configured to photograph the inner area of the semiconductor fabrication chamber before and after a cleaning process by the cleaning module;
an inspection sensor configured to detect position information of the imager with respect to the semiconductor fabrication chamber; and
an inspection controller configured to control a position of the imager based on the position information detected by the inspection sensor.

9. The apparatus of claim 8, wherein the inspection controller is configured to control a distance between the imager and the semiconductor fabrication chamber and a rotation of the imager.

10. The apparatus of claim 9, wherein the rotation of the imager comprises a roll rotated with respect to a first horizontal direction, a pitch rotated with respect to a second horizontal direction substantially perpendicular to the first horizontal direction and a yaw rotated with respect to a vertical direction.

11. The apparatus of claim 1, wherein the drive module comprises:
a vertical driver configured to move the cleaning module and the inspection module in a vertical direction;
a horizontal driver configured to move the cleaning module and the inspection module in a horizontal direction; and
a rotary driver configured to rotate the cleaning module and the inspection module with respect to the vertical direction.

12. The apparatus of claim 1, further comprising a mount module configured to removably mount the drive module to the semiconductor fabrication chamber.

13. The apparatus of claim 12, wherein the mount module comprises a mount block that is configured to be connected to the drive module and removably mounted to the semiconductor fabrication chamber together with the drive module.

14. The apparatus of claim 13, wherein the mount module further comprises a main exhauster installed at the mount block that is configured to exhaust a contaminant from the semiconductor fabrication chamber.

15. An apparatus for cleaning a semiconductor fabrication chamber, the apparatus comprising:
a cleaning module configured to clean an inner area of the semiconductor fabrication chamber in a non-contact manner;
an inspection module configured to inspect a cleaning of the semiconductor fabrication chamber by the cleaning module;
a drive module configured to move the cleaning module and the inspection module in the semiconductor fabrication chamber; and
a mount module configured to removably mount the drive module to the semiconductor fabrication chamber,
wherein the cleaning module comprises:
a non-contact type cleaner configured to clean the inner area of the semiconductor fabrication chamber in the non-contact manner;
a cleaner sensor configured to detect position information of the non-contact type cleaner with respect to the semiconductor fabrication chamber; and
a cleaner controller configured to control a position of the non-contact type cleaner based on the position information detected by the cleaner sensor, and
wherein the inspection module comprises:
an imager configured to photograph the inner area of the semiconductor fabrication chamber before and after a cleaning process by the cleaning module;
an inspection sensor configured to detect position information of the imager with respect to the semiconductor fabrication chamber; and
an inspection controller configured to control a position of the imager based on the position information detected by the inspection sensor.

16. The apparatus of claim 15, wherein the non-contact type cleaner is configured to clean the inner area of the semiconductor fabrication chamber in the non-contact manner by using a laser or dry ice.

17. The apparatus of claim 15, wherein the cleaner controller is configured to control a distance between the non-contact type cleaner and the semiconductor fabrication chamber and the cleaner controller further controls a rotation of the non-contact type cleaner.

18. The apparatus of claim 15, wherein the cleaning module further comprises a local exhauster configured to exhaust a contaminant, which is removed by the non-contact type cleaner, from the semiconductor fabrication chamber.

19. The apparatus of claim 15, wherein the mount module comprises a mount block configured to be connected to the drive module and removably mounted to the semiconductor fabrication chamber together with the drive module.

20. The apparatus of claim 19, wherein the mount module further comprises a main exhauster installed at the mount block to exhaust a contaminant from the semiconductor fabrication chamber.
